(19) United States
(12) Patent Application Publication
(10) Pub. No.: US 2025/0169065 A1
(43) Pub. Date: May 22, 2025

(54) SEMICONDUCTOR DEVICE AND METHOD OF FORMING THE SAME

(71) Applicant: Fujian Jinhua Integrated Circuit Co., Ltd., Quanzhou City (CN)

(72) Inventors: Janbo Zhang, Quanzhou City (CN); Yu-Cheng Tung, Quanzhou City (CN)

(73) Assignee: Fujian Jinhua Integrated Circuit Co., Ltd., Quanzhou City (CN)

(21) Appl. No.: 18/820,200

(22) Filed: Aug. 29, 2024

(30) Foreign Application Priority Data
Nov. 17, 2023 (CN) 202311540903.4
Nov. 17, 2023 (CN) 202323107848.8

(51) Int. Cl. H10B 12/00

(52) U.S. Cl. CPC H10B 12/485; H10B 12/0335; H10B 12/315

(57) ABSTRACT

A semiconductor device includes a substrate, a plurality of bit lines, an insulating layer and a plurality of plugs. The substrate includes a plurality of active areas. The bit lines are separated from each other and disposed on the substrate. The insulating layer overlies a top surface of the substrate. The plugs are disposed on the top surface of the insulating layer and separated from the active areas. The plugs and the bit lines are alternately arranged along a first direction, and the plugs include a plurality of first plugs and at least one second plug. Accordingly, structural defects possibly occurring in a semiconductor device can be effectively ameliorated, so as to form a semiconductor device with improved reliability of components.

### BACKGROUND OF THE INVENTION

### 1. Field of the Invention

The present invention generally relates to a semiconductor device and a method of forming the same, and more particularly, to a semiconductor device including bit lines and plugs, and a method of forming the same.

### 2. Description of the Prior Art

With the trend of miniaturization of various electronic products, the design of semiconductor devices must also meet the requirements of high integration and high density. Under the current mainstream of development trend, dynamic random access memories (DRAMs) having recessed gate structures have gradually replaced the DRAMs having only planar gate structures due to longer carrier channel length for the same semiconductor substrate so as to reduce current leakage of capacitor structures. In general, a DRAM cell with a recessed gate structure includes a transistor component and a charge storage device to receive voltage signals from bit lines and word lines. However, due to the limitations of current processing technologies, there are still many defects in currently available DRAM cells with recessed gate structures, which need to be further improved to effectively improve the performance and reliability of related memory devices.

### SUMMARY OF THE INVENTION

An object of the present invention is to provide a semiconductor device, which include a plurality of plugs disposed in a peripheral region of the semiconductor device and on a top surface of an insulating layer, to effectively ameliorate structural defects possibly occurring in the semiconductor device, thereby providing the semiconductor device with improved reliability of components.

In order to achieve the above object, an embodiment of the present invention provides a semiconductor device, which includes a substrate, a plurality of bit lines, an insulating layer and a plurality of plugs. The substrate includes a plurality of active areas. The plurality of bit lines are separated from each other and disposed on the substrate. The insulating layer overlies a top surface of the substrate. The plurality of plugs are disposed on the top surface of the insulating layer and separated from the plurality of active areas. The plurality of plugs and the plurality of bit lines are alternately arranged along a first direction, and the plurality of plugs comprise a plurality of first plugs and at least one second plug.

In order to achieve the above object, an embodiment of the present invention provides a method of forming a semiconductor, which includes the following steps. A substrate including a plurality of active areas is provided. A plurality of bit lines, which are separated from each other and disposed on the substrate, are formed. An insulating layer, which overlies a top surface of the substrate, is formed. A plurality of plugs, which are separated from the plurality of active areas, are formed on the insulating layer. The plurality of plugs and the plurality of bit lines are alternately arranged along a first direction. The plurality of plugs includes a plurality of first plugs and at least one second plug.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 4 are schematic diagrams illustrating a semiconductor device according to a preferred embodiment of the present invention, wherein:

FIG. 1 is a schematic top view of the semiconductor device according to the present invention;

FIG. 2 is a cross-sectional view taken along cut lines A-A′ and A″-A′″ shown in FIG. 1;

FIG. 3 is a cross-sectional view taken along a cut line B-B′ shown in FIG. 1; and

FIG. 4 is another cross-sectional view taken along a cut line B-B′ shown in FIG. 1.

FIG. 5 to FIG. 12 are schematic diagrams illustrating a method of forming the semiconductor device according to a preferred embodiment of the present invention, wherein:

FIG. 5 is a cross-sectional view schematically illustrating an intermediate of the semiconductor device after a first etching process is performed;

FIG. 6 is another cross-sectional view schematically illustrating an intermediate of the semiconductor device after a first etching process is performed;

FIG. 7 is a cross-sectional view schematically illustrating an intermediate of the semiconductor device after a second etching process is performed;

FIG. 8 is another cross-sectional view schematically illustrating an intermediate of the semiconductor device after a second etching process is performed;

FIG. 9 is a cross-sectional view schematically illustrating an intermediate of the semiconductor device after a semiconductor material layer is formed;

FIG. 10 is another cross-sectional view schematically illustrating an intermediate of the semiconductor device after a semiconductor material layer is formed;

FIG. 11 is a cross-sectional view schematically illustrating an intermediate of the semiconductor device after a third etching process is performed; and

FIG. 12 is another cross-sectional view schematically illustrating an intermediate of the semiconductor device after a third etching process is performed.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

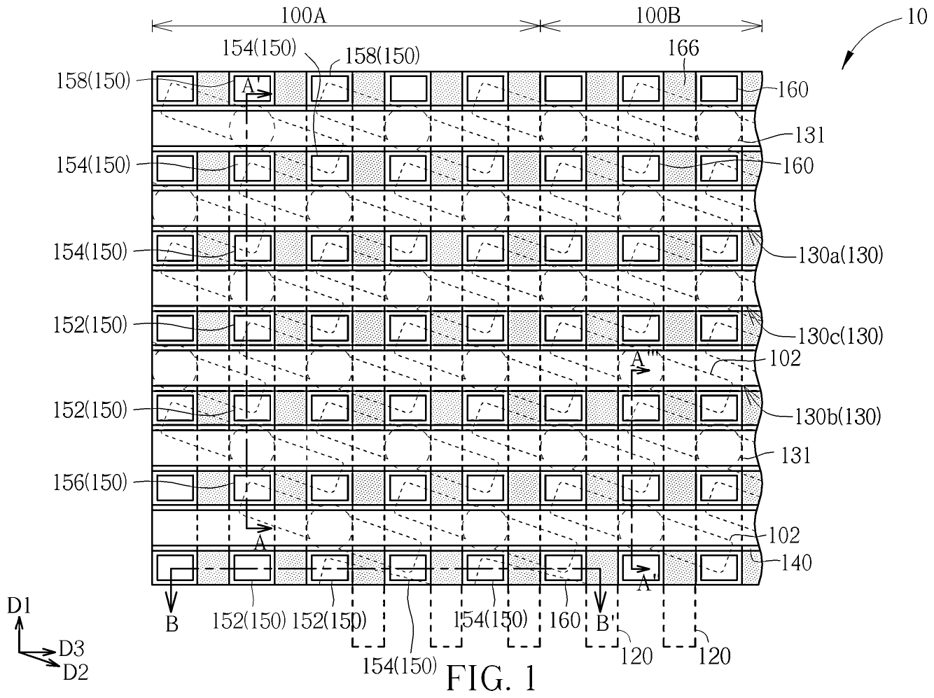

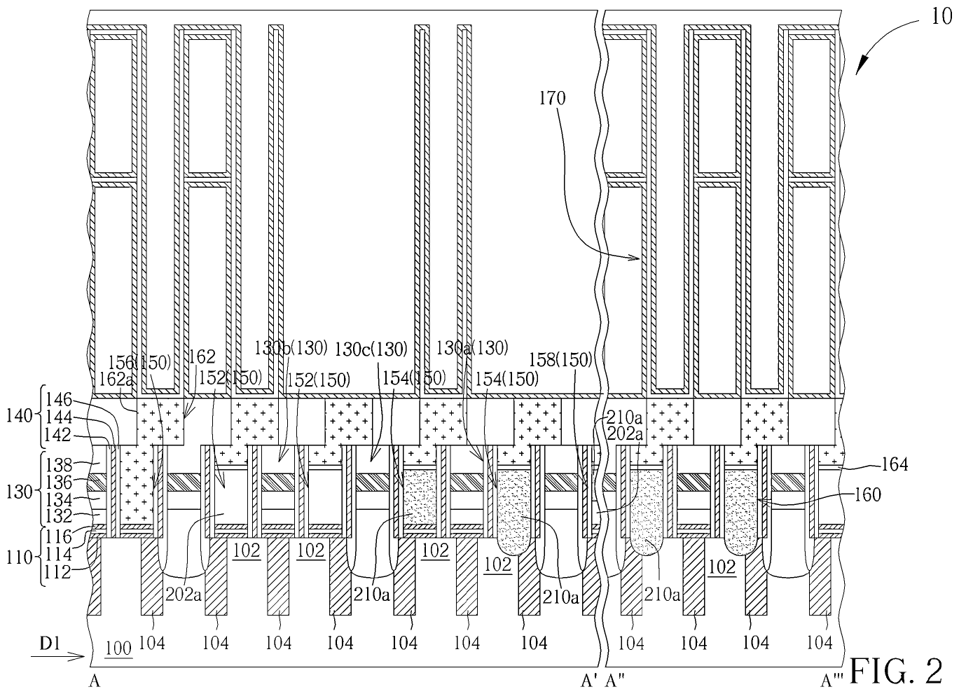

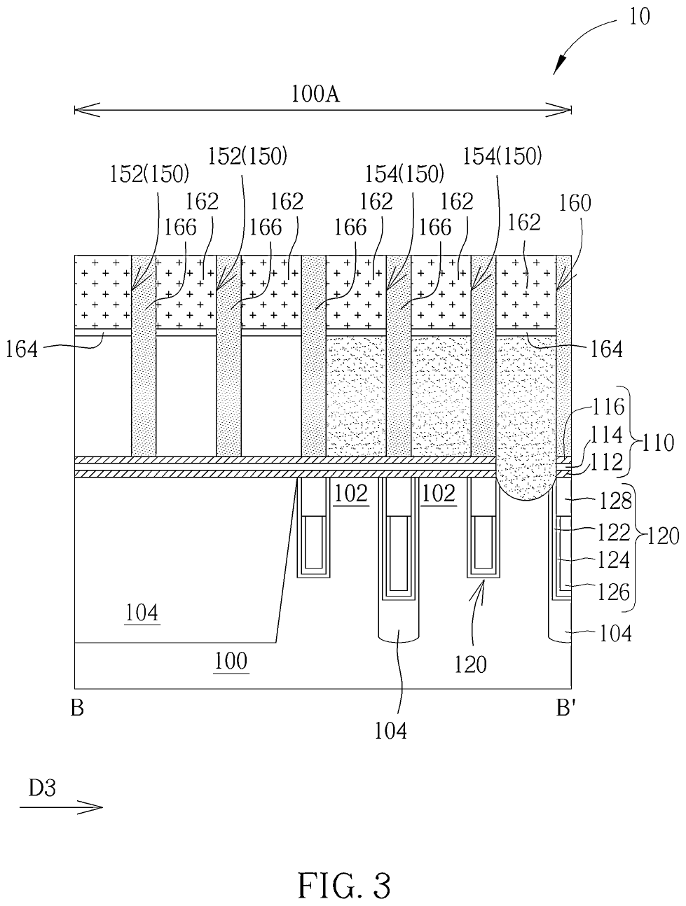

Please refer to FIG. 1 to FIG. 4, which are schematic diagrams illustrating a semiconductor device 10 according to a preferred embodiment of the present invention, wherein FIG. 1 is a schematic top view of the semiconductor device 10, and FIG. 2 to FIG. 4 are cross-sectional views of the semiconductor device 10. The semiconductor device 10 includes a substrate 100, a plurality of bit lines 130, an insulating layer 110 and a plurality of plugs 150. As shown in FIG. 1, the substrate 100 may be, for example, but not limited to, a silicon substrate, a silicon-containing substrate, e.g., SiC or SiGe, an epitaxial silicon substrate, a silicon-on-insulator (SOI) substrate, or a substrate formed of any other suitable material. A plurality of shallow trench isolations formed of, for example silicon oxide, may be further formed in the substrate 100, thereby defining a plurality of active areas 102 in the substrate 100. A plurality of bit lines 130 are separately disposed on the substrate 100 and extend along a third direction D3, while crossing the plurality of active areas 102. As shown in FIG. 2 and FIG. 3, the insulating layer 110 overlies the top surface of the substrate 100, and the plurality of plugs 150 are disposed on the top surface of the insulating layer 110 and isolated from the active areas 102. It is to be noted that along a first direction D1, the plugs 150 and the bit lines 130 are alternately arranged, and the plugs 150 further include a plurality of first plugs 152 and at least one second plug 154/156. Accordingly, by disposing the first plugs 152 and the second plug 154/156, structural defects possibly occurring in the semiconductor device 10 can be effectively ameliorated, so as to form the semiconductor device 10 with improved reliability of components.

In an embodiment, each of the first plugs 152 may include, for example, but not limited to, an insulating material 202a provided on the top surface of the insulating layer 110, e.g., silicon oxide, silicon oxynitride, etc. The second plug 154 may include, for example, but not limited to, a semiconductor material 210a provided on the top surface of the insulating layer 110, e.g., silicon (Si), silicon phosphorus (SiP). The alternative second plug 156 may further include a low-resistance metal material such as aluminum (Al), titanium (Ti), copper (Cu) or tungsten (W), preferably but not limited to tungsten. In another embodiment, the plugs 150 may further include at least one third plug 158, which may include, for example, the insulating material 202a and the semiconductor material 210a sequentially provided on the top surface of the insulating layer 110. The insulating material 202a and the semiconductor material 210a of the third plug 158 may be, for example, but not limited to, the same material as the insulating material 202a of the first plug 152 and the semiconductor material 210a of the second plug 154, respectively. It is to be noted that the semiconductor device 10, preferably, includes both a plurality of second plugs 154/156. For example, as shown in FIGS. 1 and 2, two second plugs 154 are respectively disposed at opposite sides of at least one bit line 130a along the first direction D1; two first plugs 152 are respectively disposed at opposite sides of another bit line 130b along the first direction D1; and/or one second plug 154 is disposed at a side of a further bit line 130c and one first plug 152 is disposed at the other side of the bit line 130c. However, it is not limited thereto.

Refer to FIG. 1 again. On the substrate 100 of the semiconductor device 10, there is a cell region 100B with a relatively high component integration degree in addition to a peripheral region 100A with a relatively low component integration degree. The cell region 100B, for example, is disposed adjacent to the peripheral region 100A, but it is not limited thereto. Furthermore, the above-described first plugs 152, second plug 154 and third plug 158 are all disposed in the peripheral region 100A, and in the cell region 100B, a plurality of storage node contacts 160 are disposed and electrically connected to corresponding active areas 102. In an embodiment, the storage node contacts 160 may include a semiconductor material, for example, but not limited to, silicon, silicon phosphorous, etc. It is preferred but not limited to that the semiconductor material is the same as the semiconductor material 210a of the second plug 154. In this embodiment, the active areas 102 are separated from each other and extend along a second direction D2, and furthermore, allocated as an array. On the other hand, the storage node contacts 160 and the plugs 150 are allocated as another array and partially overlap the underlying active areas 102, but some of the plugs 150 do not overlap any active area 102.

The semiconductor device 10 further includes a plurality of word lines 120 separately disposed in the substrate 100 and extending along the first direction D1 and a plurality of bit line spacers 140 and a plurality of isolation structures 166 disposed on the substrate 100. It is understood by those of ordinary skill in the art that the extending directions of the active areas 102, word lines 120 and bit lines 130 are different from one another. The extending direction of the word lines 120, i.e., the first direction D1, should be perpendicular to the extending direction of the bit lines 130, i.e., the third direction D3, while interleaving with both the active areas 102 and the bit lines 130. In detail, as shown in FIG. 1 and FIG. 2, in the first direction D1, the plugs 150 or the storage node contacts 160 are alternately arranged with the bit lines 130 at intervals. Furthermore, each of the bit lines 130 is separated from a corresponding one of the plugs 150, or each of the bit lines 130 is separated from a corresponding one of the storage node contacts 160, by one of the bit line spacers 140 disposed on the sidewalls of the bit lines 130.

As shown in FIG. 2, each of the bit lines 130 further includes a semiconductor layer 132 formed of a semiconductor material such as polycrystalline silicon, doped amorphous silicon, etc., a barrier layer 134 formed of a barrier material such as titanium and/or titanium nitride, tantalum and/or tantalum oxide, etc., a metal layer 136 formed of a low-resistance metal material such as tungsten, aluminum, copper, etc., and a capping layer 138 formed of an insulating material such as silicon oxide, silicon nitride, silicon oxynitride, etc. Furthermore, a portion of the semiconductor layer 132 extends into the substrate 100 to form a bit line contact (BLC) 131. Each of the bit lines 130 is electrically connected to the active areas 102 through the bit line contact 131 correspondingly formed thereunder. The bit line spacers 140, in detail, may include spacers 142 (for example, silicon nitride or silicon carbonitride), spacers 144 (for example, silicon oxide or silicon oxynitride) and spacers 146 (for example, silicon nitride or silicon carbonitride), which are stacked in sequence, but it is not limited thereto. It is to be noted that the bottommost surface of the second plug 154 is lower than a bottom surface of the metal layer 136 of each of the bit lines 130, and the topmost surface of the semiconductor material 210a of the second plug 154 is higher than a top surface of the metal layer 136 of each of the bit lines 130. Furthermore, the topmost surface of the semiconductor material 210a of the third plug 158 is also higher than the top surface of the metal layer 136 of each of the bit lines 130. In an embodiment, top surfaces of the insulating materials 202a of the first plugs 152 may have various heights, and all the top surfaces of the insulating materials 202a are higher than the top surface of the metal layer 136 of each of the bit lines 130.

Refer to FIG. 2 again. The semiconductor device 10 further includes a plurality of conductive pads 162 and a plurality of capacitors 170 disposed above the plugs 150 and the storage node contacts 160. Each of the connection pads 162 is in physical contact with a corresponding one of the plugs 150 and a corresponding one of the storage node contacts 160. Furthermore, each of the conductive pads 162 is partially disposed on the capping layer 138 of the bit line 130, so that a portion 162a of the connection pad 162 is higher than the topmost surface of the bit line 130. It is to be noted that the conductive pads 162 are omitted from FIG. 1 and the capacitors 170 are omitted from FIG. 3, so that the arrangement of the plug 150 and the storage plug 160 can be clearly shown. Those of ordinary skill in the art may readily infer the relative positions of the conductive pads 162 in FIG. 1 with reference to FIG. 2 or FIG. 3.

In an embodiment, a metal silicide layer 164 may be further disposed above each the first plugs 152, second plug 154 and third plug 158. For example, the metal silicide layer 164 is disposed between the first plug 152 or second plug 154 and a corresponding one of the conductive pads 162, or disposed between the semiconductor material 210a of the third plug 158 and a corresponding one of the conductive pads 162. In another embodiment, the conductive pads 162 may include, for example, but not limited to, a low-resistance metal material such as aluminum, titanium, cupper, tungsten, etc., and preferably, tungsten or the same metal material as the second plug 156. The second plug 156 and the conductive pads 162 disposed on the second plug 156 can thus be integrally formed. The capacitors 170 within the cell region 100B are aligned with the storage node contacts 160 respectively for electrically connecting thereto. The capacitors 170 within the peripheral region 100A are only aligned with a portion of the first plugs 152, the second plugs 154, 156 and the third plug 158, with no capacitor being disposed over at least one of the first plugs 152, the second plugs 154, 156 and the third plug 158, as shown in FIG. 2.

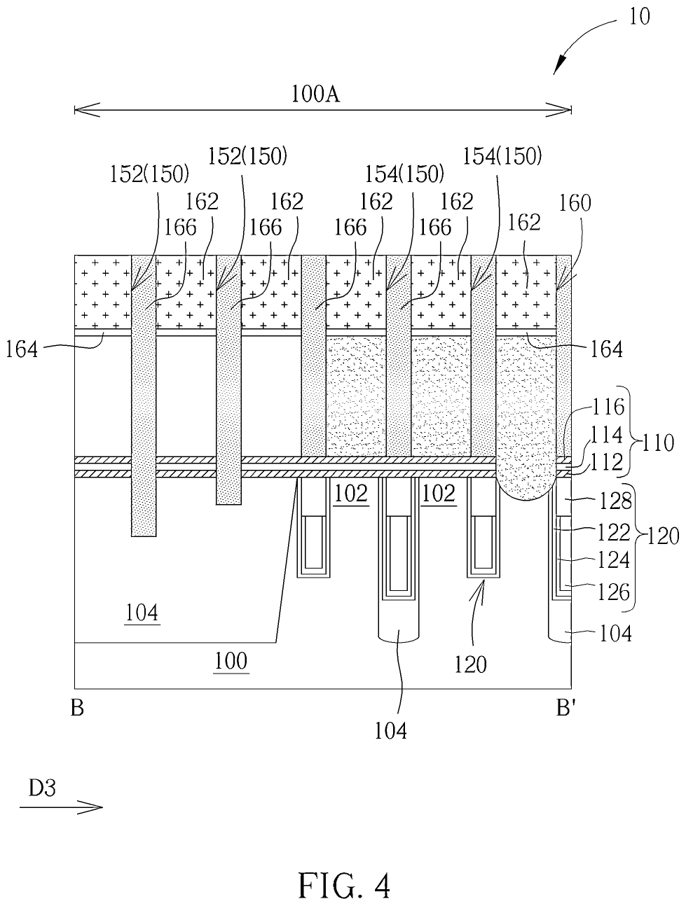

On the other hand, as shown in FIG. 1 and FIG. 3, the plugs 150 or the storage node contacts 160 are alternately arranged at intervals with the word lines 120 in the substrate 100 along the third direction D3. Furthermore, the isolation structures 166 are disposed right above the word lines 120, respectively, for electrically insulating adjacent plugs 150 and/or storage node contacts 160. In an embodiment, the isolation structures 166 are formed of, for example, but not limited to, an insulating material such as silicon nitride or silicon carbonitride, etc, and which are disposed over the insulating layer 110. However, in another embodiment, the isolation structures 166 may optionally penetrate through the insulating layer 110 and extended into a portion of the shallow trench isolations 104, as shown in FIG. 4. As shown in FIG. 3, each of the word lines 120, in detail, includes a dielectric layer 122, a gate dielectric layer 124 and a gate electrode 126, which are stacked in sequence, and a cap layer 128 overlying the gate electrode 126. A surface of the cap layer 128 is in flush with the top surface of the substrate 100, so that the word lines 120 may serve as buried word lines (BWL) of the semiconductor device 10. The word lines 120 are isolated from the bit lines 130 on the substrate 100 by the insulating layer 110. In an embodiment, the insulating layer 110 is preferably a composite layer, for example, but not limited to, an oxide 112-nitride 114-oxide 116 (ONO) stacked layer.

The luminous flux in the cell region 100B and the peripheral region 100A of the semiconductor device 10 according to the present invention, where respective component integration degrees are very different, can be equalized in the photolithography process of the plugs 150 by disposing the first plugs 152 and/or second plug 154/156 on the top surface of the insulating layer 110 in the peripheral region 100A, so that the manufacturing yield of the semiconductor device can be enhanced. Accordingly, structural defects possibly occurring in the semiconductor device 10 can be effectively ameliorated, so as to form the semiconductor device 10 with improved component configuration and operational performance. In this configuration, the semiconductor device 10 in this embodiment may be used as a dynamic random access memory (DRAM) device, and at least one of the capacitors 170 arranged above the storage plugs 160 within the cell region 100B and at least one transistor element (not shown) arranged in the substrate 100 constitute the smallest memory cell in the DRAM array for receiving voltage information from the bit lines 130 and the word lines 120.

In order to make the semiconductor device 10 of the present invention easily understood by those of ordinary skill in the art, a method of forming the semiconductor device 10 according to the present invention will be further described hereinafter.

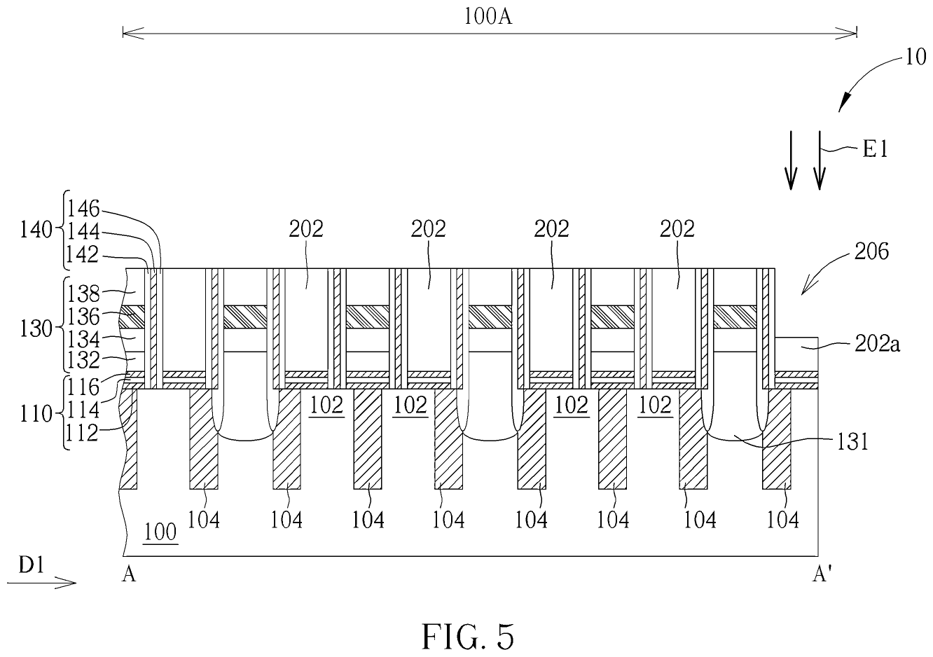

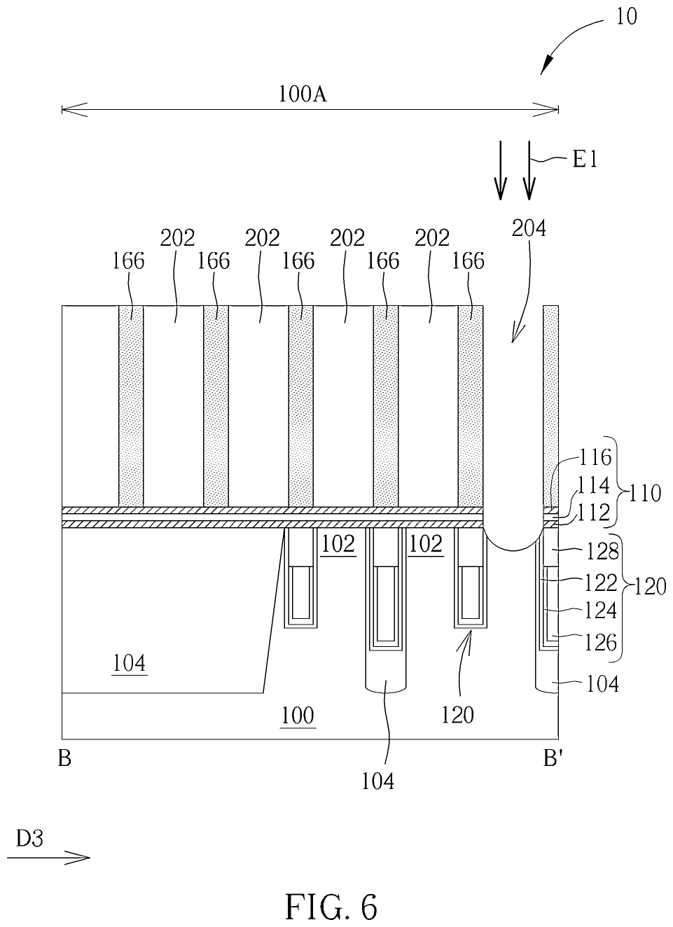

Please refer to FIG. 5 to FIG. 12, which are schematic diagrams illustrating a method of forming the semiconductor device according to a preferred embodiment of the present invention. FIGS. 5, 7, 9 and 11 are cross-sectional views taken along a cut line A-A′ shown in FIG. 1, which schematically illustrate intermediates of the semiconductor device 10 in the manufacturing process. FIGS. 6, 8, 10 and 12 are cross-sectional views taken along a cut line B-B′ shown in FIG. 1, which schematically illustrate intermediates of the semiconductor device 10 in the manufacturing process. Although top views of the intermediates of the semiconductor device 10 in the manufacturing process are not shown herein, those of ordinary skill in the art can clearly understand the specific positions of the cut lines A-A′ and B-B′ on the semiconductor device 10 and readily infer the top view of the intermediates of the semiconductor device 10 in the manufacturing process by referring to the top view of the semiconductor device 10 shown in FIG. 1.

First of all, as shown in FIG. 5 and FIG. 6, a substrate 100 is provided. Shallow trench isolations 104 are formed in the substrate 100 to define active areas 102 in the substrate 100. In an embodiment, the shallow trench isolations 104 are formed by, for example, but not limited to, etching the substrate 100 to form a plurality of trenches (not shown) and then filling at least one insulating material, e.g., silicon oxide, into the trenches to form the shallow trench isolations 104 having respective top surfaces in flush with a top surface of the substrate 100. Subsequently, a plurality of word lines 120 are formed in the substrate 100 along the first direction D1. In an embodiment, a method of forming the word lines 120 includes, for example, but not limited to, the following steps. A plurality of trenches (not shown) penetrating through both active areas 102 and shallow trench isolations 104 are formed. Dielectric layers 122 formed in the trenches and covering all the surfaces of the trenches, gate dielectric layers 124 covering the surfaces of lower parts of the trenches, gate electrodes 126 filling the lower parts of the trenches, and cap layers 128 filling upper parts of the trenches are then sequentially formed. Furthermore, an insulating layer 110 and a plurality of bit lines 130 extending along the third direction D3 are formed on the substrate 100, wherein the bit lines 130 are electrically connected to the active areas 102 through bit line plugs 131 formed under corresponding bit lines 130. In an embodiment, a method of forming the bit lines 130 and the bit line plugs 131 includes, for example, but not limited to, the following steps. First of all, openings (not shown) penetrating through the insulating layer 110 and partially exposing the surface of the substrate 100 are formed by using a mask layer (not shown). A semiconductor material (not shown) such as polycrystalline silicon or doped amorphous silicon is formed on the substrate 100 and fills the openings. Subsequently, a barrier material layer (not shown) containing a barrier material such as titanium and/or titanium nitride or tantalum and/or tantalum oxide, a metal material layer (not shown) containing a low-resistance metal material such as tungsten, aluminum or cupper, and a capping material layer (not shown) containing an insulating material such as silicon oxide, silicon nitride or silicon oxynitride, are sequentially formed on the substrate 100. Finally, by way of a patterning process, the bit lines 130 and the bit line plugs 131 are simultaneously formed. Afterwards, a depositing process and an etching back process are sequentially performed to deposit an insulating material layer 202 on the insulating layer 110 to fill gaps between the bit lines 130. The insulating material layer 202 includes, for example, but not limited to, an insulating material such as silicon oxide or silicon oxynitride.

Refer to FIG. 5 and FIG. 6 again. A first mask layer (not shown) is formed on the insulating material layer 202, and a first etching process E1 is performed on the insulating material layer 202 with the first mask layer, thereby forming at least one first plug hole 204, whose bottom exposes a corresponding one of the active areas 102, and another plug hole 206, which has the insulating material 202a of the insulating material layer 202 remaining at bottom thereof without exposing any active area 102. It is to be noted that only one first plug hole 204 and one plug hole 206 are shown in the drawings in this embodiment. Those of ordinary in the art, however, may understand from the top view of FIG. 1, the method in this embodiment can form a plurality of first plug holes 204 and a plurality of plug holes 206 at the same time by the first etching process E1. The first mask layer is then completely removed.

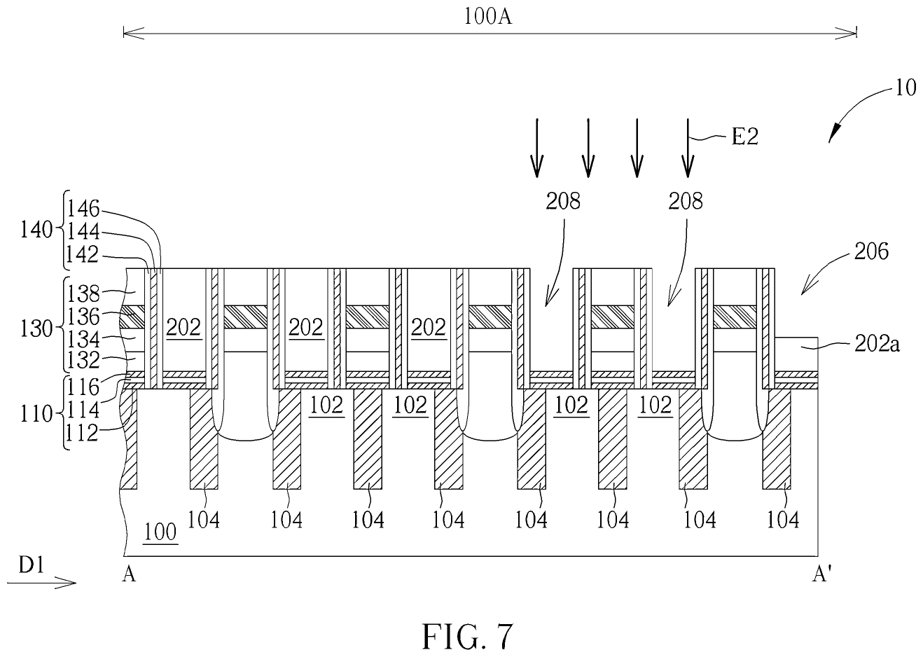

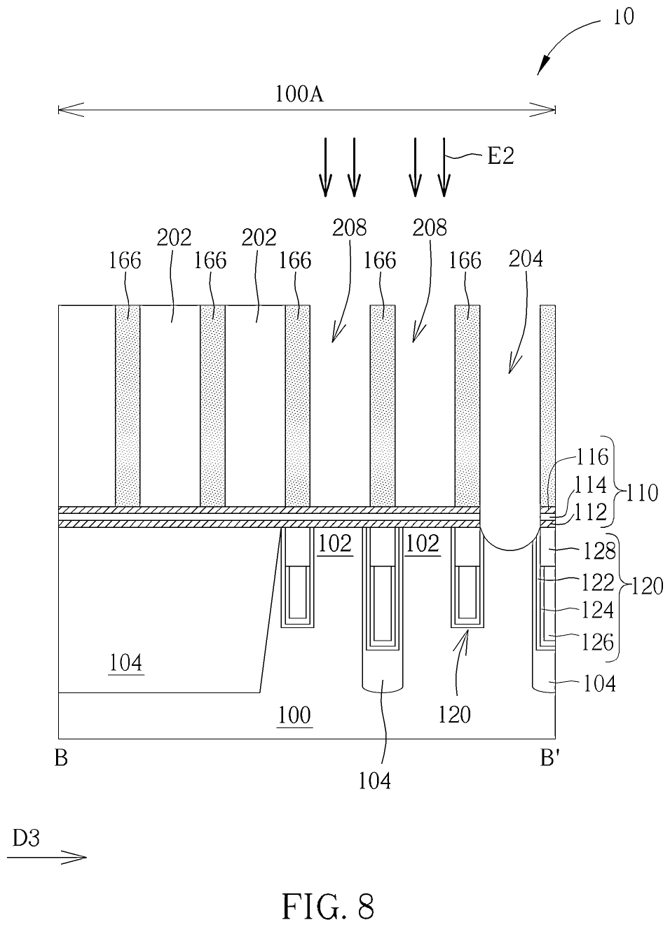

As shown in FIG. 7 and FIG. 8, a second mask layer (not shown) is formed on the insulating material layer 202, and a second etching process E2 is performed on the insulating material layer 202 with the second mask layer, thereby forming a plurality of second plug holes 208, whose bottom partially exposes the top surface of the insulating layer 110. The second mask layer is then completely removed.

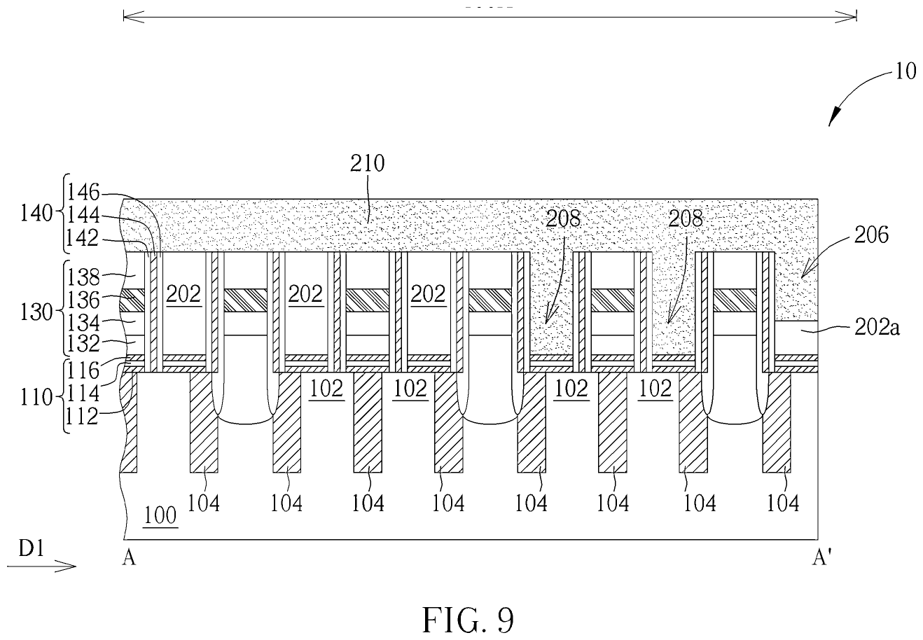

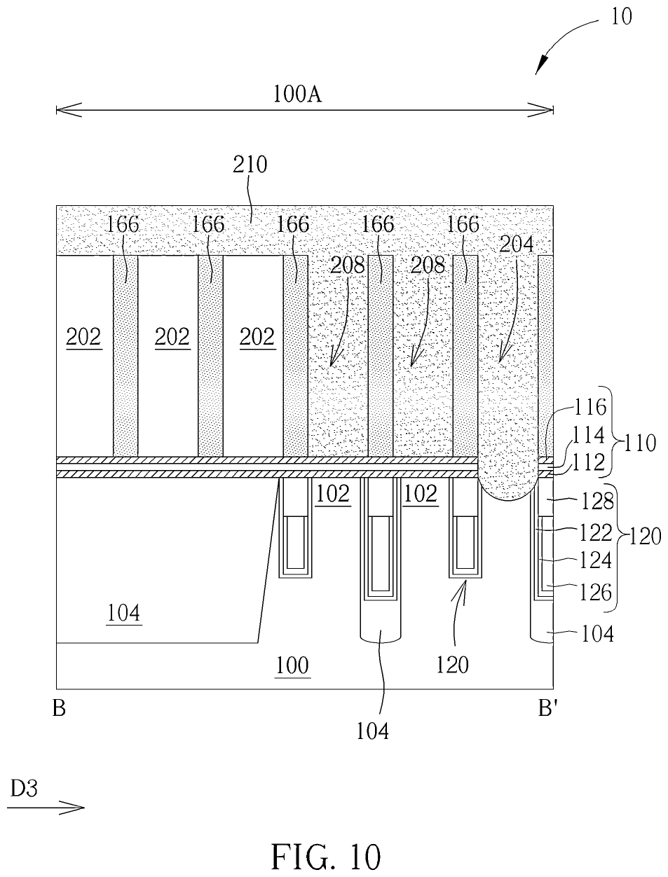

As shown in FIG. 9 and FIG. 10, after the second etching process E2, a semiconductor material layer 210 is formed and fills the first pug hole(s) 204, the plug hole(s) 206 and the second plug holes 208.

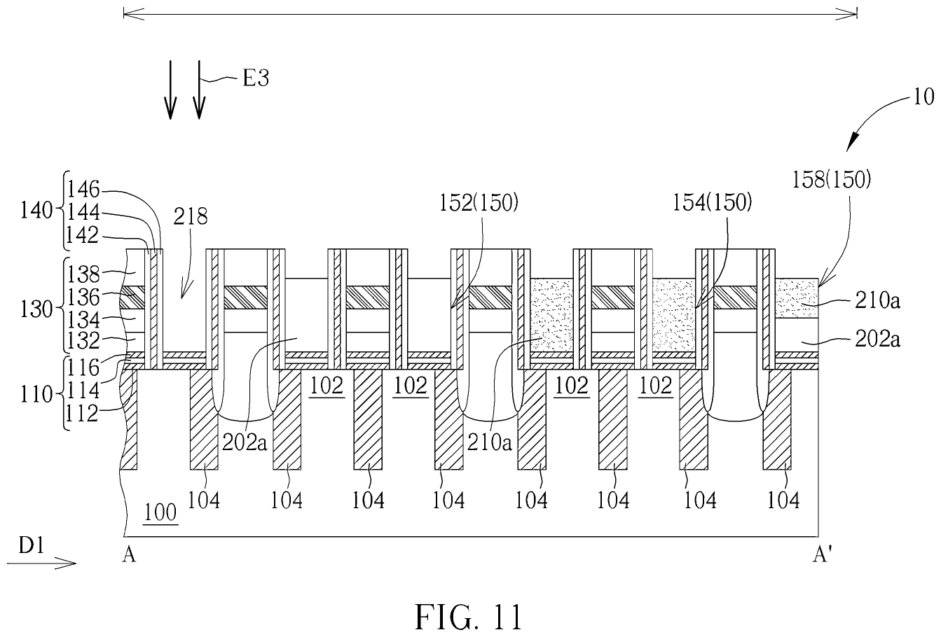

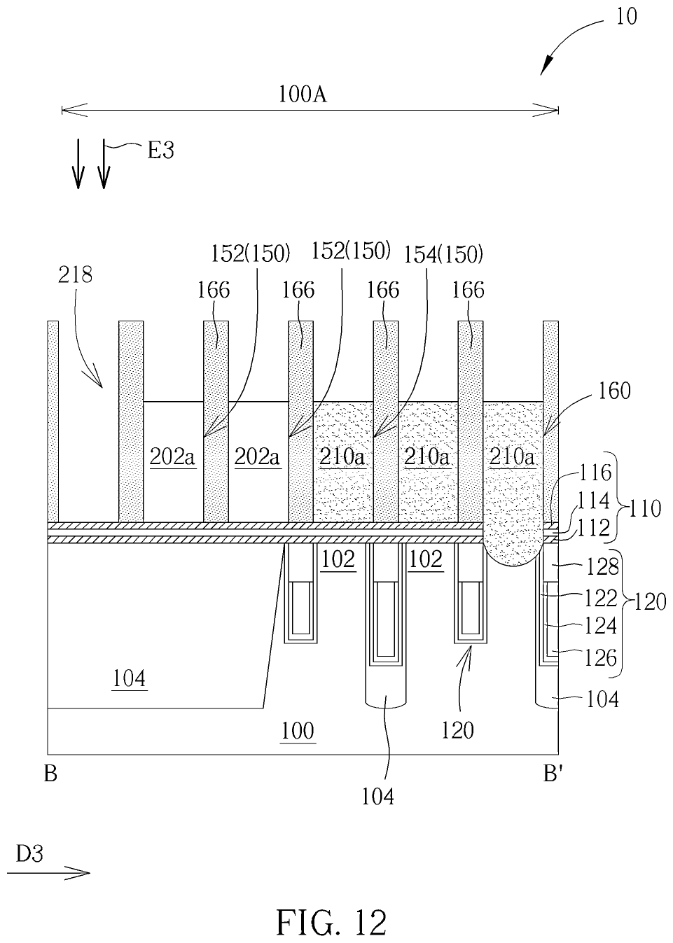

As shown in FIG. 11 and FIG. 12, an etching back process is performed on the insulating material layer 202. According to a proper etching selectivity ratio between the insulating material layer 202 and the semiconductor material layer 210, the semiconductor material layer 210 filled in the first pug hole 204 and the plug hole 206 can be partially removed, so that the semiconductor material layer 210 filled in the first pug hole 204 forms a cell plug 160 and the semiconductor material layer 210 filled in the pug hole 206 forms a third plug 158 together with the insulating layer 202a disposed thereunder. Furthermore, the semiconductor material layer 210 filled in the second pug holes 208 forms second plugs 154. Meanwhile, the semiconductor material layer 210 partially filled in the gaps between the bit lines 130 forms first plugs 152.

Subsequently, refer to FIG. 11 and FIG. 12 again. A third mask layer (not shown) is formed, and a third etching process E3 is performed on the remaining insulating material layer 202, thereby forming at least one third plug hole 218, whose bottom partially exposes the top surface of the insulating layer 110. Then at least one depositing process is continuously performed on the substrate 100, thereby forming a metal silicide layer 164 on the cell plug 160, the first plugs 152, the second plugs 154 and the third plug 158, and forming a conductive material layer (not shown) on the metal silicide layer 164 and filling the third plug hole 218. Subsequently, a plurality of conductive pads 162 electrically connected to the cell plug 150, the first plugs 152, the second plugs 154 and the third plug 158 are formed by a patterning process. The conductive material layer filled into the third plug hole 218 also forms second plugs 156 (see FIG. 1). Accordingly, the second plugs 156 and the connection pad 162 electrically connected thereto form an integrated continuous layer, but it is not limited thereto. In an embodiment, the continuous layer may include, for example, but not limited to, a low-resistance metal material such as aluminum, titanium, copper or tungsten, and preferably tungsten. Subsequently, a depositing process and an etching back process are continuously performed. After an insulating material (not shown) is filled into gaps among the conductive pads 162, the semiconductor 10 as shown in FIG. 1, FIG. 2 and FIG. 3 can be formed.

Based on the above-described manufacturing process, a method of forming the semiconductor device 10 according to an embodiment of the present invention can be accomplished. In the peripheral region 100A, the first plugs 152 and/or the second plug 154/156 are formed on the top surface of the insulating layer 110. In this way, when a photolithography process of the plugs 150 is performed, consistent luminous flux can be ensured in the cell region 100B and the peripheral region 100A, where respective component integration degrees are very different, thereby improving a manufacturing yield of the semiconductor device. Accordingly, possible structural defects occurring in the semiconductor device 10 can be ameliorated so as to form a semiconductor device with better component structure and functions and enhanced operational performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate comprising a plurality of active areas;
a plurality of bit lines separated from each other and disposed on the substrate;
an insulating layer overlying a top surface of the substrate; and
a plurality of plugs disposed on a top surface of the insulating layer and separated from the plurality of active areas, wherein the plurality of plugs and the plurality of bit lines are alternately arranged along a first direction, and the plurality of plugs comprise a plurality of first plugs and at least one second plug.

2. The semiconductor device according to claim 1, wherein the plurality of first plugs comprise an insulating material, and the at least one second plug comprise a metal material or a semiconductor material.

3. The semiconductor device according to claim 2, wherein the plurality of plugs comprise a plurality of second plugs, and at least one of the plurality of bit lines is disposed with two of the plurality of second plugs at opposite sides thereof, respectively.

4. The semiconductor device according to claim 1, further comprising a plurality of conductive pads disposed above the plurality of plugs, respectively, the at least one second plug and one of the plurality of conductive pads disposed thereabove are monolithic, and a portion of the one of the plurality of conductive pads is higher than a topmost surface of the plurality of bit lines.

5. The semiconductor device according to claim 1, further comprising:
a plurality of conductive pads disposed above the plurality of plugs, respectively; and
a plurality of metal silicide layers disposed above the plurality of first plugs and between the plurality of first plugs and the plurality of conductive pads disposed above the plurality of first plugs.

6. The semiconductor device according to claim 1, wherein each of the plurality of bit lines comprises a semiconductor layer, a metal layer and a cap layer stacked in sequence, and a bottommost surface of the at least one second plug is lower than the metal layer of each of the plurality of bit lines.

7. The semiconductor device according to claim 6, wherein the plurality of plugs further comprise at least one third plug, and the at least one third plug comprises an insulating material and a semiconductor material stacked in sequence.

8. The semiconductor device according to claim 7, wherein a topmost surface of the semiconductor material of the at least one third plug is higher than the metal layer of each of the plurality of bit lines.

9. The semiconductor device according to claim 6, wherein top surfaces of the insulating material in the plurality of first plugs are not of the same height and all higher than the metal layer of each of the plurality of bit lines.

10. A method of forming a semiconductor device, comprising:
providing a substrate, the substrate comprising a plurality of active areas;
forming a plurality of bit lines, the plurality of bit lines being separated from each other and disposed on the substrate;
forming an insulating layer on the substrate and overlying a top surface of the substrate; and
forming a plurality of plugs on the insulating layer, the plurality of plugs being separated from the plurality of active areas, wherein the plurality of plugs and the plurality of bit lines are alternately arranged along a first direction, and the plurality of plugs comprise a plurality of first plugs and at least one second plug.

11. The method of forming a semiconductor device according to claim 10, further comprising:
forming a plurality of storage node contacts on the substrate, wherein the plurality of storage node contacts penetrate through the insulating layer and are in physical contact with the active areas, respectively.

12. The method of forming a semiconductor device according to claim 11, further comprising:
depositing an insulating material layer on the insulating layer, wherein the insulating material layer is filled into gaps between the plurality of bit lines;
forming a first mask layer on the insulating material layer;
using the first mask layer to perform a first etching process on the insulating material layer and the insulating layer, thereby forming a plurality of first plug holes exposing the active areas;
forming the plurality of storage node contacts in the plurality of first plug holes, respectively; and
forming the plurality of first plugs and the at least one second plug.

13. The method of forming a semiconductor device according to claim 12, further comprising:
forming a second mask layer on the insulating material layer; and
using the second mask layer to perform a second etching process on the insulating material layer before the plurality of storage node contacts are formed, thereby forming at least one second plug hole exposing the insulating layer.

14. The method of forming a semiconductor device according to claim 13, further comprising:
removing the first mask layer before performing the second etching process; and
forming a semiconductor material layer, which is filled into the plurality of first plug holes and the at least one second plug hole.

15. The method of forming a semiconductor device according to claim 14, forming the plurality of plugs further comprising:
partially removing the insulating material layer at a side of at least one of the plurality of bit lines in the first etching process, thereby forming a plug hole, which does not expose the insulating layer; and
filling the semiconductor material layer in the plug hole to form a third plug.

16. The method of forming a semiconductor device according to claim 12, further comprising:
forming a third mask layer on the insulating material layer; and
using the third mask layer to perform a third etching process on the insulating material layer after the plurality of storage node contacts are formed, thereby forming at least one third plug hole exposing the insulating layer.

17. The method of forming a semiconductor device according to claim 16, further comprising:
forming a conductive material layer, filled into the at least one third plug hole, after the third etching process.

18. The method of forming a semiconductor device according to claim 12, further comprising:
forming a plurality of conductive pads disposed above the plurality of first plugs and the at least one second plug, respectively, wherein a portion of the plurality of conductive pads overlies topmost surfaces of the plurality of bit lines.

19. The method of forming a semiconductor device according to claim 18, further comprising:
forming metal silicide layers on the plurality of first plugs before forming the plurality of conductive pads.

20. The method of forming a semiconductor device according to claim 12, wherein forming the plurality of plugs further comprises:
remaining a portion of the insulating material layer between the plurality of bit lines to form the plurality of first plugs.
